(19) United States
(12) Patent Application Publication
(10) Pub. No.: US 2026/0198190 A1
(43) Pub. Date: Jul. 9, 2026

(54) DISPLAY DEVICE AND ELECTRONIC DEVICE INCLUDING THE SAME

(71) Applicant: Samsung Display Co., Ltd., Yongin-Si (KR)

(72) Inventors: Byung Chang YU, Yongin-si (KR); Kyung Ho KIM, Yongin-si (KR); YUNMI KIM, Yongin-si (KR); Hyeong Seok KIM, Yongin-si (KR); Do Yeong PARK, Yongin-si (KR); Dong Hee SHIN, Yongin-si (KR); Jin Joo HA, Yongin-si (KR)

(21) Appl. No.: 19/271,821

(22) Filed: Jul. 17, 2025

(30) Foreign Application Priority Data
Jan. 3, 2025 (KR) 10-2025-0000972

(51) Int. Cl. H10K 59/131; G09G 3/3233; G09G 3/3266

(52) U.S. Cl. CPC H10K 59/131; G09G 3/3233; G09G 3/3266; G09G 2300/0819; G09G 2300/0842; G09G 2310/08

(57) ABSTRACT

A display device includes: a display panel including a display area and a non-display area; and a gate driver including gate drive circuits and clock signal lines. The non-display area includes a gate drive circuit area where the gate drive circuits are located, a clock signal line area where the clock signal lines transmitting clock signals are located, and a load matching area between the gate drive circuit area and the clock signal line area. The gate drive circuits include a second-1 gate drive circuit and a second-2 gate drive circuit disposed along a first direction, and a sum of distances between four clock signal lines electrically connected to the second-1 gate drive circuit and the second-1 gate drive circuit is substantially equal to a sum of distances between four clock signal lines electrically connected to the second-2 gate drive circuit and the second-2 gate drive circuit.

### CROSS-REFERENCE TO RELATED APPLICATIONS

This application claims priority to and benefits of Korean Patent Application No. 10-2025-0000972 filed on Jan. 3, 2025, the disclosure of which is incorporated herein by reference in its entirety.

### BACKGROUND

### 1. Field

This disclosure relates to a display device and an electronic device including the same.

### 2. Description of the Related Art

The display device may include a display panel where pixels for displaying images are arranged. The pixels may include pixel circuits, and a gate driver for providing scan signals to the pixel circuits may be integrated into the display panel.

### SUMMARY

A gate driver of a display device may include drive circuits and clock signal lines for transmitting clock signals to the drive circuits. As the number of clock signal lines increases, the length deviation of clock connection lines connecting the clock signal lines and drive circuits may become larger, which may require a load matching area to match the resistance of the clock connection lines. The load matching area may increase the width of the display panel, which may result in an increase in the dead space of the display device.

Embodiments provide a display device and an electronic device including the same capable of reducing load deviation that may occur due to the position and arrangement of clock signal lines.

According to an embodiment, a display device includes a display panel including a display area where pixels displaying images are located and a non-display area adjacent to the display area, and a gate driver including gate drive circuits providing scan signals to the pixels and clock signal lines transmitting clock signals to the gate drive circuits. The non-display area includes a drive circuit area where the gate drive circuits are located, a clock signal line area where clock signal lines transmitting clock signals are located, and a load matching area between the gate drive circuit area and the clock signal line area. The gate drive circuits include a second-1 gate drive circuit and a second-2 gate drive circuit disposed along a first direction, and a sum of distances between four clock signal lines among the clock signal lines electrically connected to the second-1 gate drive circuit and the second-1 gate drive circuit is substantially equal to a sum of distances between four clock signal lines among the clock signal lines electrically connected to the second-2 gate drive circuit and the second-2 gate drive circuit.

The display device may further include clock connection lines electrically connecting the clock signal lines and the second-1 and second-2 gate drive circuits. The clock connection lines may be bent in the load matching area.

The clock signals may include first to twelfth clock signals sequentially phase-delayed. The four clock signal lines electrically connected to the second-1 gate drive circuit may transmit third to sixth clock signals, and the four clock signal lines electrically connected to the second-2 gate drive circuit may transmit ninth to twelfth clock signals.

The second-1 gate drive circuit may be electrically connected to clock signal lines transmitting the first and second clock signals among the clock signal lines, and the second-2 gate drive circuit may be electrically connected to clock signal lines transmitting the seventh and eighth clock signals among the clock signal lines.

The clock signal lines may include first to twelfth clock signal lines sequentially positioned in a second direction crossing the first direction. The first to twelfth clock signal lines may not sequentially transmit the first to twelfth clock signals.

The first to fourth clock signal lines may each transmit one of the first, second, seventh, and eighth clock signals.

The fifth and twelfth clock signal lines may each transmit one of the third and fifth clock signals, the sixth and eleventh clock signal lines may each transmit one of the fourth and sixth clock signals, the seventh and tenth clock signal lines may each transmit one of the ninth and eleventh clock signals, and the eighth and ninth clock signal lines may each transmit one of the tenth and twelfth clock signals.

The fifth and twelfth clock signal lines may each transmit one of the fourth and sixth clock signals, the sixth and eleventh clock signal lines may each transmit one of the ninth and eleventh clock signals, the seventh and tenth clock signal lines may each transmit one of the tenth and twelfth clock signals, and the eighth and ninth clock signal lines may each transmit one of the third and fifth clock signals.

The fifth and twelfth clock signal lines may each transmit one of the ninth and eleventh clock signals, the sixth and eleventh clock signal lines may each transmit one of the tenth and twelfth clock signals, the seventh and tenth clock signal lines may each transmit one of the third and fifth clock signals, and the eighth and ninth clock signal lines may each transmit one of the fourth and sixth clock signals.

The fifth and twelfth clock signal lines may each transmit one of the tenth and twelfth clock signals, the sixth and eleventh clock signal lines may each transmit one of the third and fifth clock signals, the seventh and tenth clock signal lines may each transmit one of the fourth and sixth clock signals, and the eighth and ninth clock signal lines may each transmit one of the ninth and eleventh clock signals.

According to an embodiment, an electronic device includes a display module, a processor, and a memory. The display module includes a display panel including a display area where pixels displaying images are located and a non-display area adjacent to the display area, a gate driver including gate drive circuits providing scan signals to the pixels and clock signal lines transmitting clock signals to the gate drive circuits. The non-display area includes a drive circuit area where the gate drive circuits are located, a clock signal line area where the clock signal lines transmitting clock signals are located, and a load matching area between the gate drive circuit area and the clock signal line area. The gate drive circuits include a second-1 gate drive circuit and a second-2 gate drive circuit disposed along a first direction, and a sum of distances between four clock signal lines among the clock signal lines electrically connected to the second-1 gate drive circuit and the second-1 gate drive circuit is substantially equal to a sum of distances between four clock signal lines among the clock signal lines electrically connected to the second-2 gate drive circuit and the second-2 gate drive circuit.

According to embodiments, the load deviation that may occur due to the position and arrangement of clock signal lines can be reduced, and accordingly, the dead space of the display device can be reduced.

In addition, according to embodiments, there are advantageous effects that can be recognized throughout the specification.

### BRIEF DESCRIPTION OF THE DRAWINGS

FIG. 1 is a block diagram of an electronic device according to an embodiment.

FIG. 2 illustrates schematic diagrams of electronic devices according to various embodiments.

FIG. 3 is a schematic plan view of a display device according to an embodiment.

FIG. 4 is a schematic diagram of an equivalent circuit of one pixel of a display device according to an embodiment.

FIG. 5 is a schematic diagram illustrating a gate driver of a display device according to an embodiment.

FIG. 6 is a diagram illustrating connection between clock signal lines and drive circuits in a display device according to an embodiment.

FIG. 7 is a waveform diagram of clock signals input to a gate driver of a display device according to an embodiment.

FIG. 8, FIG. 9, FIG. 10, FIG. 11, and FIG. 12 are diagrams each illustrating clock signals transmitted through clock signal lines of a second clock signal line group and connection with a second gate drive circuit in a display device according to an embodiment.

FIG. 13 is a schematic cross-sectional view of a display area of a display device according to an embodiment.

### DETAILED DESCRIPTION

Various embodiments will be described in detail with reference to the accompanying drawings to enable one skilled in the art to easily implement them.

When a part such as a layer, film, region, or plate is stated to be “on” or “above” another part, this includes not only cases where it is “directly on” the other part but also cases where there is another structure between them. Conversely, when a part is stated to be “directly on” another part, it means there is no other structure between them.

In the specification, when a part is described as “including” a component, unless stated otherwise, this means it may include other components as well.

In the specification, “connected” means not only direct connection between two or more components but also indirect connection through other components, physical or electrical connection, as well as connection between parts that are substantially integrated but may be referred to by different names according to their position or function.

In the drawings, symbols “DR1”, “DR2”, and “DR3” are used to indicate directions, where “DR1” is a first direction, “DR2” is a second direction that may be perpendicular to the first direction, and “DR3” is a third direction that may be perpendicular to both the first and second directions. The first direction (DR1), second direction (DR2), and third direction (DR3) may correspond to the width direction, length direction, and thickness direction of the display device, respectively.

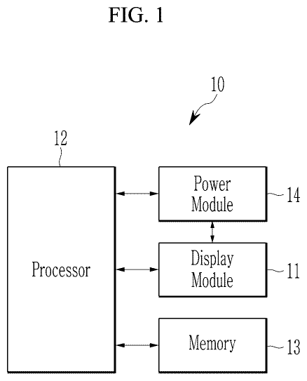

FIG. 1 is a block diagram of an electronic device according to an embodiment.

Referring to FIG. 1, an electronic device 10 according to an embodiment may include a display module 11, a processor 12, a memory 13, a power module 14, and so forth.

The display module 11 may include a display panel, a driver, and so forth. The display panel may include pixels displaying images and may provide a display screen. The driver may process signals and supply them to the display panel for displaying images on the display screen. The driver may be provided in the form of an integrated circuit chip.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, image data signals and/or input control signals are transmitted to the display module 11, and the display module 11 may process the received signals to display images through the display screen.

The power module 14 may include a power supply module such as a power adapter or battery device, and a power conversion module that converts power supplied by the power supply module to generate power necessary for the operation of the electronic device 10.

At least one of the aforementioned components of the electronic device 10 may be included in a display device according to embodiments. Also, among individual modules functionally included in one module, some may be included in the display device while others may be provided separately from the display device. For example, the display device may include the display module 11, and the processor 12, memory 13, and power module 14 may be provided in the form of other devices within the electronic device 10 rather than in the display device.

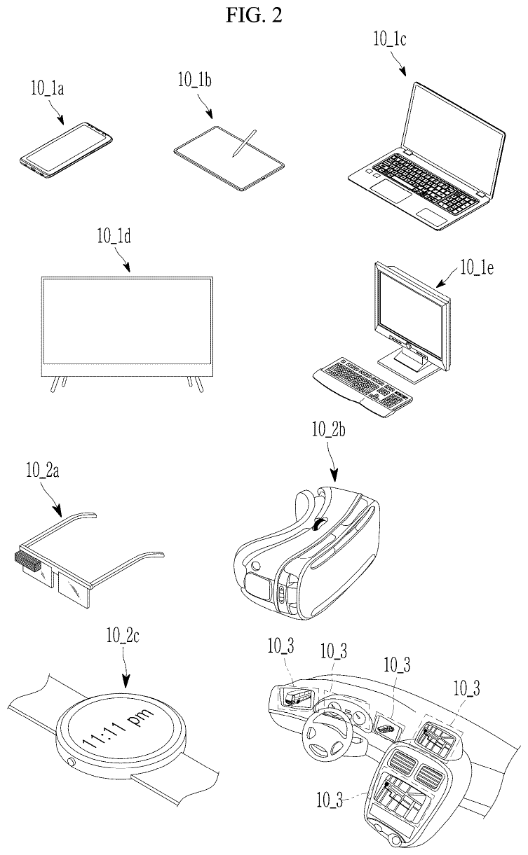

FIG. 2 illustrates schematic diagrams of electronic devices according to various embodiments.

The display device according to embodiments may be applied to various electronic devices. Referring to FIG. 2, various electronic devices incorporating the display device according to embodiments may include image display electronic devices such as smartphones 10_1a, tablet PCs 10_1b, laptops 10_1c, TVs 10_1d, and desktop monitors 10_1e. Additionally, the electronic devices may include wearable electronic devices with display modules such as smart glasses 10_2a, head-mounted displays 10_2b, smartwatches 10_2c, and vehicle electronic devices 10_3 including display modules or display devices placed in vehicle instrument panels, center fascias, dashboards, such as CID (Center Information Display), room mirror displays, and so forth.

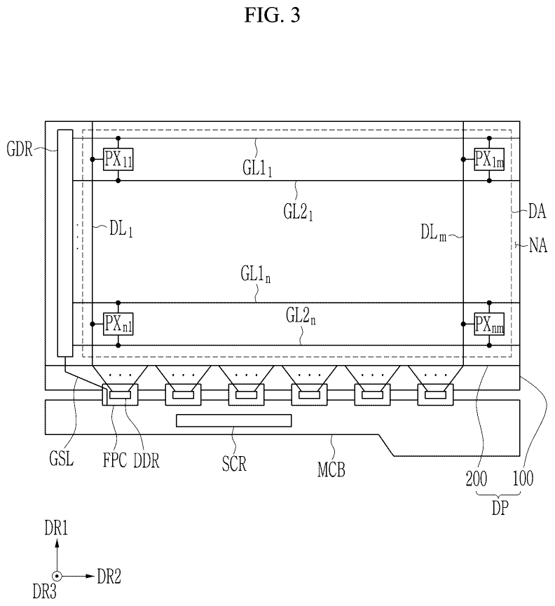

FIG. 3 is a schematic plan view of a display device according to an embodiment.

Referring to FIG. 3, a display device (or display module) according to an embodiment may include a display panel DP, a gate driver GDR, a data driver DDR, a signal controller SCR, and so forth.

The display panel DP may include a display area DA corresponding to a display screen displaying images, and a non-display area NA where various circuits and/or lines for generating and/or transmitting signals applied to the display area DA are arranged. The non-display area NA may be adjacent to the display area DA and may surround the display area DA. In FIG. 3, the area inside the dotted rectangle may be the display area DA and the area outside the dotted rectangle may be the non-display area NA.

The display panel DP may include a display portion 100 and a color conversion portion 200. The display portion 100 and the color conversion portion 200 may be bonded together by a sealant located at the edge of the display panel DP between the display portion 100 and the color conversion portion 200. The color conversion portion 200 may overlap entirely with the display portion 100, but the display portion 100 may include an area not covered by the color conversion portion 200 for connecting or bonding a flexible circuit board FPC. The display portion 100 may include a pad portion (not shown) for connecting or bonding the flexible circuit board FPC, and the color conversion portion 200 may be formed shorter than the display portion 100 at the bottom of the display panel DP where the pad portion is located so that the pad portion can be exposed externally. The display portion 100 and color conversion portion 200 may each include a substrate. The display portion 100, color conversion portion 200, the substrate of the display portion 100, and the substrate of the color conversion portion 200 may each include areas corresponding to the display area DA and non-display area NA of the display panel DP.

Pixels PX₁₁~PXₙₘ may be located in the display area DA of the display panel DP. The pixels PX₁₁~PXₙₘ may be arranged in a matrix. First gate lines GL1₁~GL1ₙ transmitting first scan signals, second gate lines GL2₁~GL2ₙ transmitting second scan signals, and data lines DL₁~DLₘ transmitting data voltages may be located in the display area DA. The data lines DL₁~DLₘ may extend in the first direction DR1, and the first and second gate lines GL1₁~GL1ₙ, GL2₁~GL2ₙ may extend in the second direction DR2. The first and second gate lines GL1₁~GL1ₙ and GL2₁~GL2ₙ may be connected to the gate driver GDR, and the data lines DL1~DLm may be connected to the data driver DDR. The first and second gate lines GL11~GL1n and GL2₁~GL2ₙ and data lines DL₁~DLₘ may be connected to the pixels PX₁₁~PXₙₘ. The pixels PX₁₁~PXₙₘ may receive data voltages at specific timings according to the first scan signals.

The gate driver GDR and data driver DDR may receive control signals from the signal controller SCR. The signal controller SCR may be located on the main circuit board MCB. The signal controller SCR may receive image data and control signals (synchronization signals, clock signals, enable signals, or the like) from devices such as, for example, a graphics processing unit. Some of the received control signals may be transmitted to the gate driver GDR, and some of the control signals and image data may be transmitted to the data driver DDR.

Based on control signals received from the signal controller SCR through the signal line GSL, the gate driver GDR may generate and output first and second scan signals to the first and second gate lines GL1₁~GL1ₙ and GL2₁~GL2ₙ. The gate driver GDR may be located in the non-display area NA. The gate driver GDR may be located on one side or both sides of the display area DA. In FIG. 3, one gate driver GDR is shown on the left side of the display area DA, but a gate driver GDR may also be located on the right side of the display area DA. The gate driver GDR may be formed on the substrate through the same thin-film process as the pixels PX₁₁~PXₙₘ.

Based on image data and control signals (hereinafter, referred to as data control signals) received from the signal controller SCR, the data driver DDR may generate and output data voltages to the data lines DL₁~DLₘ. The data driver DDR may be mounted on the flexible circuit board FPC in the form of an integrated circuit chip. The flexible circuit board FPC may electrically connect the main circuit board MCB and the display panel DP. The data driver DDR may also be located in the non-display area NA of the display panel DP.

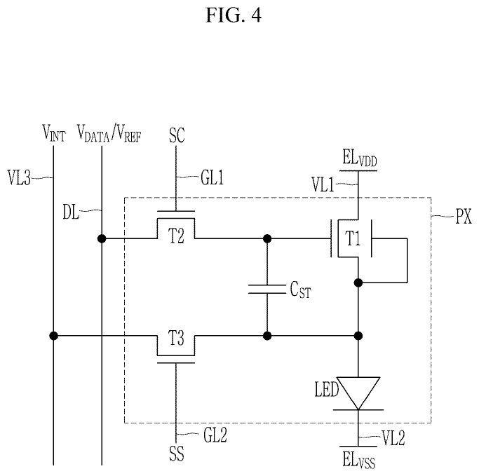

FIG. 4 is a schematic diagram of an equivalent circuit of one pixel of a display device according to an embodiment.

Referring to FIG. 4, a pixel PX may include first to third transistors T1-T3, a storage capacitor CST, and a light emitting diode LED. The light emitting diode LED may be an organic or inorganic light emitting diode. The first to third transistors T1-T3 may be N-type transistors, or at least some may be P-type transistors.

The gate electrode of the first transistor T1 may be connected to the first electrode of the storage capacitor C_{ST}. The first electrode of the first transistor T1 may be connected to a driving voltage line VL1 transmitting a driving voltage EL_{VDD}, and the second electrode of the first transistor T1 may be connected to the anode of the light emitting diode LED and the second electrode of the storage capacitor C_{ST}. The first transistor T1 may supply driving current to the light emitting diode LED according to the voltage stored in the storage capacitor C_{ST}, which receives the data voltage V_{DATA} through the switching operation of the second transistor T2.

The gate electrode of the second transistor T2 may be connected to the first gate line GL₁ transmitting the first scan signal SC. The first electrode of the second transistor T2 may be connected to a data line DL that can transmit data voltage V_{DATA} or reference voltage V_{REF}. The second electrode of the second transistor T2 may be connected to the first electrode of the storage capacitor C_{ST} and the gate electrode of the first transistor T1. The second transistor T2 may turn on according to the first scan signal SC to transmit the reference voltage V_{REF} or data voltage V_{DATA} to the gate electrode of the first transistor T1.

The gate electrode of the third transistor T3 may be connected to the second gate line GL2 transmitting the second scan signal SS. The first electrode of the third transistor T3 may be connected to an initialization voltage line VL3 transmitting an initialization voltage V_{INT}. The second electrode of the third transistor T3 may be connected to the second electrode of the storage capacitor C_{ST}, the second electrode of the first transistor T1, and the anode. The third transistor T3 may turn on according to the second scan signal SS to transmit the initialization voltage V_{INT} to the anode to initialize the voltage of the anode.

The first electrode of the storage capacitor C_{ST} may be connected to the gate electrode of the first transistor T1, and the second electrode of the storage capacitor C_{ST} may be connected to the second electrode of the third transistor T3 and the anode. The cathode of the light emitting diode LED may be connected to a common voltage line VL2 transmitting a common voltage EL_{VSS}. Each light emitting diode LED may constitute one pixel PX, and the anode and cathode of the light emitting diode LED may be called a pixel electrode and a common electrode, respectively.

The light emitting diode LED may emit light with brightness (grayscale) according to the driving current generated by the first transistor T1.

An example of the operation of the circuit shown in FIG. 4, particularly the operation during one frame, will be explained for the case where transistors T1~T3 are all N-type transistors.

When a frame begins, during the initialization period, a high-level voltage of the common voltage EL_{VSS} may be applied while the first scan signal SC and second scan signal SS are at a low level. This prevents the light emitting diode LED from emitting light by preventing current from flowing through it. Also, the initialization voltage V_{INT} may be applied through the initialization voltage line VL3 to initialize the initialization voltage line VL3. Subsequently, high-level first scan signal SC and high-level second scan signal SS may be supplied to turn on the second transistor T2 and third transistor T3. Through the turned-on second transistor T2, reference voltage V_{REF} from the data line DL may be supplied to the gate electrode of the first transistor T1 and the first electrode of the storage capacitor C_{ST}, and, through the turned-on third transistor T3, initialization voltage V_{INT} may be supplied to the second electrode of the first transistor T1 and the anode. Accordingly, during the initialization period, the anode may be initialized to the initialization voltage V_{INT}. The voltage difference (V_{REF}−V_{INT}) between the reference voltage V_{REF} and initialization voltage V_{INT} may be stored in the storage capacitor C_{ST}.

Next, during the sensing period, high-level first scan signal SC and high-level second scan signal SS may be maintained. The initialization voltage line VL3 may be disconnected from the initialization voltage V_{INT} supply source and may function as a sensing line. Through the second transistor T2, the gate electrode of the first transistor T1 and the first electrode of the storage capacitor C_{ST} may maintain the reference voltage V_{REF}. Accordingly, when the voltage of the second electrode becomes “reference voltage V_{REF}−threshold voltage V_{TH}”, the first transistor T1 may be switched from a turn-on state to turn-off state, and the initialization voltage line VL3 may be charged up to “reference voltage V_{REF}−threshold voltage V_{TH}”. Here, the threshold voltage V_{TH} represents the threshold voltage of the first transistor T1. The initialization voltage line VL3 charged to “reference voltage V_{REF}−threshold voltage V_{TH}” may be connected to an external circuit, and the external circuit may sense the voltage of the initialization voltage line VL3 to extract the threshold voltage V_{TH} of the first transistor T1. By generating compensated data signals during the sensing period reflecting the sensed characteristic information, characteristic variations of the first transistor T1 that may differ for each pixel PX can be compensated.

Next, during the data input period, high-level first scan signal SC may be supplied and low-level second scan signal SS may be supplied, and through the turned-on second transistor T2, data voltage V_{DATA} from the data line DL may be supplied to the gate electrode of the first transistor T1 and the first electrode of the storage capacitor C_{ST}. The data voltage V_{DATA} may have a compensated value based on the sensing of the threshold voltage V_{TH} of the first transistor T1, and, through this, the characteristic variation of the first transistor T1 can be corrected. When the data voltage V_{DATA} is applied, the second electrode of the first transistor T1 and the anode may maintain almost the same potential as in the sensing period due to the turned-off state of the first transistor T1.

Next, during the emission period, the first transistor T1 turned on by the data voltage V_{DATA} transmitted to its gate electrode may generate driving current according to the data voltage V_{DATA}, and the light emitting diode LED may emit light by that driving current. That is, the brightness of the light emitting diode LED can be adjusted by controlling the driving current supplied to the light emitting diode LED according to the magnitude of the data voltage V_{DATA} applied to the pixel PX.

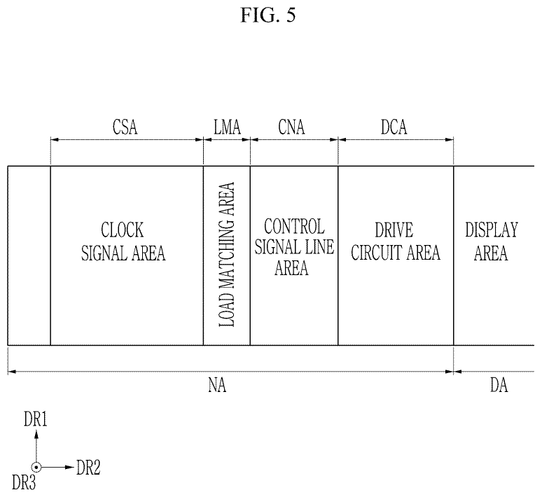

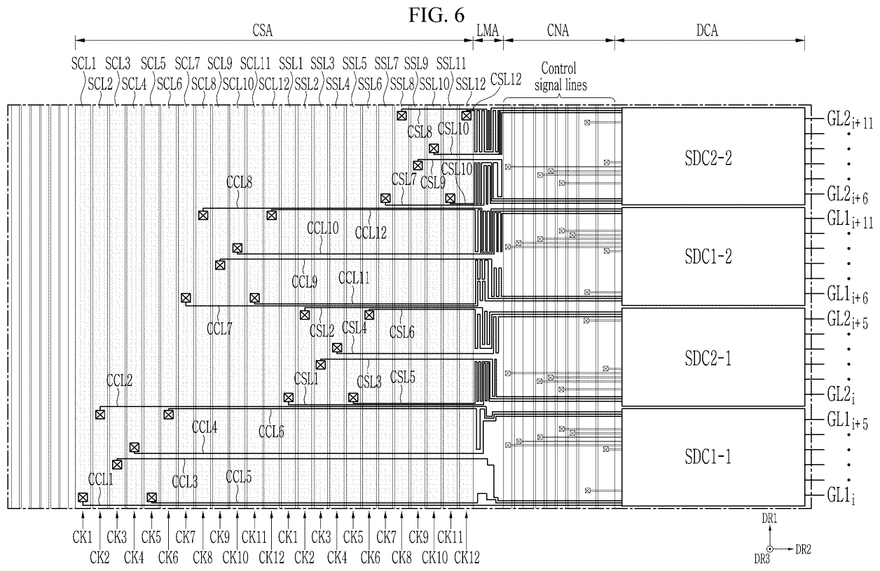

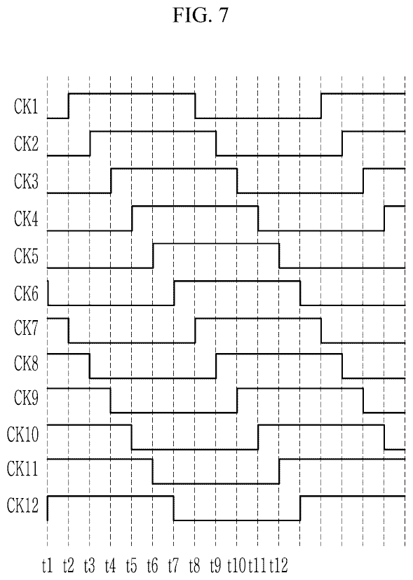

FIG. 5 is a schematic diagram illustrating a gate driver of a display device according to an embodiment, and FIG. 6 is a diagram illustrating connection between clock signal lines and drive circuits in a display device according to an embodiment. FIG. 7 is a waveform diagram of clock signals input to a gate driver of a display device according to an embodiment.

Referring to FIG. 5 and FIG. 6, the gate driver GDR may include a clock signal line area CSA, a load matching area LMA, a control signal line area CNA, and a drive circuit area DCA. The drive circuit area DCA may be adjacent to the display area DA, and the clock signal line area CSA may be located farther from the display area DA than the drive circuit area DCA. The load matching area LMA may be located between the drive circuit area DCA and the clock signal line area CSA. The gate driver GDR shown may be located on the left side of the display area DA. In case that the gate driver GDR is located on the right side of the display area DA, the arrangement of the areas of the gate driver GDR may be symmetrical with respect to the display area DA.

First and second gate drive circuits SDC1 and SDC2 may be located in the drive circuit area DCA. The first gate drive circuit SDC1 may include a pair of first gate drive circuits SDC1-1 and SDC1-2 disposed along the first direction DR1. The second gate drive circuit SDC2 may include a pair of second gate drive circuits SDC2-1 and SDC2-2 disposed along the first direction DR1. Although FIG. 6 shows two of the first gate drive circuits SDC1-1 and SDC1-2 and two of the second gate drive circuits SDC2-1 and SDC2-2, the first gate drive circuits SDC1-1 and SDC1-2 and second gate drive circuits SDC2-1 and SDC2-2 may be alternately positioned one by one along the first direction DR1. That is, in the first direction DR1, the first gate drive circuit SDC1-1 (hereinafter, also referred to as first-1 gate drive circuit), the second gate drive circuit SDC2-1 (hereinafter, also referred to as second-1 gate drive circuit), the first gate drive circuit SDC1-2 (hereinafter, also referred to as first-2 gate drive circuit), and the second gate drive circuit SDC2-2 (hereinafter, also referred to as second-2 gate drive circuit) may be repeatedly positioned. The first gate drive circuits SDC1-1 and SDC1-2 and second gate drive circuits SDC2-1 and SDC2-2 may include electrically connected transistors and capacitors.

The first gate drive circuit SDC1 may be connected to the first gate lines GL1₁~GL1ₙ and may output the first scan signal SC. The second gate drive circuit SDC2 may be connected to the second gate lines GL2₁~GL2ₙ and may output the second scan signal SS. One first gate drive circuit SDC1-1 or SDC1-2 may be connected to at least four first gate lines and may output at least four first scan signals SC with different timings to the at least four first gate lines by receiving at least four clock signals with different timings. One second gate drive circuit SDC2-1 or SDC2-2 may be connected to at least four second gate lines and may output at least four second scan signals SS with different timings to the at least four second gate lines by receiving at least four clock signals with different timings.

For example, one first gate drive circuit SDC1-1 or SDC1-2 may be connected to six first gate lines (e.g., GL1ᵢ~GL1ᵢ₊₅ or GL1ᵢ₊₆~GL1ᵢ₊₁₁) and may output six first scan signals SC with different timings to the six first gate lines. One second gate drive circuit SDC2-1 or SDC2-2 may be connected to six second gate lines (e.g., GL2ᵢ~GL2ᵢ₊₅ or GL2ᵢ₊₆~GL2ᵢ₊₁₁) and may output six second scan signals SS with different timings to the six second gate lines. Two first gate drive circuits SDC1-1 and SDC1-2 disposed along the first direction DR1 may be connected to twelve first gate lines (e.g., GL1ᵢ~GL1ᵢ₊₁₁) and may output twelve first scan signals SC with different timings to the twelve first gate lines. Two second gate drive circuits SDC2-1 and SDC2-2 disposed along the first direction DR1 may be connected to twelve second gate lines (e.g., GL2ᵢ~GL2ᵢ₊₁₁) and may output twelve second scan signals SS with different timings to the twelve second gate lines. The number of gate lines connected to the first gate drive circuits SDC1-1 and SDC1-2 and second gate drive circuits SDC2-1 and SDC2-2 may be varied according to design.

Clock signal lines SCL1~SCL12, SSL1~SSL12 may be located in the clock signal line area CSA. The clock signal lines SCL1~SCL12, SSL1~SSL12 may extend in the first direction DR1. The clock signal lines SCL1~SCL12, SSL1~SSL12 may include a first clock signal line group including first to twelfth clock signal lines SCL1~SCL12 for transmitting first to twelfth clock signals CK1~CK12 to the first gate drive circuits SDC1, and a second clock signal line group including first to twelfth clock signal lines SSL1~SSL12 for transmitting first to twelfth clock signals CK1~CK12 to the second gate drive circuits SDC2. The first to twelfth clock signal lines SCL1~SCL12 may be sequentially positioned in the second direction DR2. The first to twelfth clock signal lines SSL1~SSL12 may be sequentially positioned in the second direction DR2. In each clock signal line group, the first clock signal line SCL1 or SSL1 may be located farther from the drive circuit area DCA than the twelfth clock signal line SCL12 or SSL12. The first clock signal line group may be located farther from the drive circuit area DCA than the second clock signal line group. Alternatively, the second clock signal line group may be located farther from the drive circuit area DCA than the first clock signal line group.

The first to twelfth clock signals CK1~CK12 may have different phases. Referring to FIG. 7, the phases of the first to twelfth clock signals CK1~CK12 may be sequentially delayed at equal intervals. The second clock signal CK2 may have a phase that is delayed by 1/12 compared to the first clock signal CK1. The third clock signal CK3 may have a phase that is delayed by 1/12 compared to the second clock signal CK2. The fourth clock signal CK4 may have a phase that is delayed by 1/12 compared to the third clock signal CK3. The fifth clock signal CK5 may have a phase that is delayed by 1/12. The sixth clock signal CK6 may have a phase that is delayed by 1/12 compared to the fifth clock signal CK5. The seventh clock signal CK7 may have a phase that is delayed by 1/12 compared to the sixth clock signal CK6. The eighth clock signal CK8 may have a phase that is delayed by 1/12 compared to the seventh clock signal CK7. The ninth clock signal CK9 may have a phase that is delayed by 1/12 compared to the eighth clock signal CK8. The tenth clock signal CK10 may have a phase that is delayed by 1/12 compared to the ninth clock signal CK9. The eleventh clock signal CK11 may have a phase that is delayed by 1/12 compared to the tenth clock signal CK10. The twelfth clock signal CK12 may have a phase that is delayed by 1/12 compared to the eleventh clock signal CK11. The seventh to twelfth clock signals CK7~CK12 may be inverted signals of the first to sixth clock signals CK1~CK6. Each of the first to twelfth clock signals CK1~CK12 may have a 50% duty ratio.

The clock signal lines SCL1~SCL12 and SSL1~SSL12 may be connected to the first and second gate drive circuits SDC1 and SDC2 by clock connection lines CCL1~CCL12 and CSL1~CSL12, respectively. Among the clock signal lines SCL1~SCL12 of the first clock signal line group, six clock signal lines (e.g., SCL1~SCL6) may be connected to one of the first gate drive circuits SDC1-1 and SDC1-2 by six clock connection lines CCL1~CCL6, and the remaining six clock signal lines (e.g., SCL7~SCL12) may be connected to the other of the first gate drive circuits SDC1-1 and SDC1-2 by six clock connection lines CCL7~CCL12. Each first gate drive circuit SDC1-1 or SDC1-2 may receive six clock signals CK1~CK6 or CK7~CK12 with different timings to output six first scan signals SC. A pair of first gate drive circuits SDC1-1 and SDC1-2 may receive first to twelfth clock signals CK1~CK12 to output twelve first scan signals SC. Among the clock signal lines SSL1~SSL12 of the second clock signal line group, six clock signal lines (e.g., SSL1~SSL6) may be connected to one of the second gate drive circuits SDC2-1 and SDC2-2 by six clock connection lines CSL1~CSL6, and the remaining six clock signal lines (e.g., SSL7~SSL12) may be connected to the other of the second gate drive circuits SDC2-1 and SDC2-2 by six clock connection lines CSL7~CSL12. Each second gate drive circuit SDC2-1 or SDC2-2 may receive six clock signals CK1~CK6 or CK7~CK12 with different timings to output six second scan signals SS. A pair of second gate drive circuits SDC2-1 and SDC2-2 may receive first to twelfth clock signals CK1~CK12 to output twelve second scan signals SS.

Due to the distance difference between the first to twelfth clock signal lines SCL1~SCL12 and the first gate drive circuit SDC1, the lengths of the clock connection lines CCL1~CCL12 may be different. For example, since the first clock signal line SCL1 is located farther from the first gate drive circuit SDC1 than the sixth clock signal line SCL6, when forming the clock connection lines CCL1~CCL12 as straight lines extending in the second direction DR2, the length of the first clock connection line CSL1 connecting the first clock signal line SCL1 and the first gate drive circuit SDC1 may be longer than the length of the sixth clock connection line CSL6 connecting the sixth clock signal line SCL6 and the first gate drive circuit SDC1. The resistance difference due to the length difference between the clock connection lines CCL1~CCL12 may cause different RC delays of the clock signals CK1~CK12, leading to image quality deterioration. By placing a load matching area LMA between the clock signal line area CSA and the drive circuit area DCA and by forming clock connection lines (e.g., CCL12) connected to relatively closer clock signal lines (e.g., SCL12) longer than clock connection lines (e.g., CCL7) connected to relatively farther clock signal lines (e.g., SCL7) in the load matching area LMA, the length difference and resistance difference between the clock connection lines CCL1~CCL12 can be reduced. The increase in length of the clock connection lines CCL1~CCL12 in the load matching area LMA can be achieved by forming the clock connection lines CCL1~CCL12 in a meandering pattern, minimizing the load matching area LMA.

In the load matching area LMA corresponding to one first gate drive circuit SDC1-1 or SDC1-2 (i.e., in the area aligned with the first gate drive circuit SDC1-1 or SDC1-2 in the second direction DR2 within the entire load matching area LMA), six clock connection lines CCL1~CCL6 or CCL7~CCL12 may be located. The load matching area LMA corresponding to one first gate drive circuit SDC1-1 or SDC1-2 may include two areas in the first direction DR1, and three clock connection lines may be located in each area.

Similarly, due to the distance difference between the first to twelfth clock signal lines SSL1~SSL12 and the second gate drive circuit SDC2, the lengths of the clock connection lines CSL1~CSL12 may be different. In the load matching area LMA, by forming clock connection lines (e.g., CSL12) connected to relatively closer clock signal lines (e.g., SSL12) longer than clock connection lines (e.g., CSL7) connected to relatively farther clock signal lines (e.g., SSL7), the length difference and resistance difference between the clock connection lines CSL1~CSL12 can be reduced and deterioration of display quality can be prevented.

In the load matching area LMA corresponding to one second gate drive circuit SDC2-1 or SDC2-2, six clock connection lines CSL1~CSL6 or CSL7~CSL12 may be located. The load matching area LMA corresponding to one second gate drive circuit SDC2-1 or SDC2-2 may include two areas in the first direction DR1 and three clock connection lines may be located in each area.

Control signal lines transmitting control signals to the first gate drive circuits SDC1 and second gate drive circuits SDC2 may be located in the control signal line area CNA. The signal lines may extend in the first direction DR1. The signal lines may include signal lines transmitting a low voltage, signal lines transmitting gate control signals, and so forth.

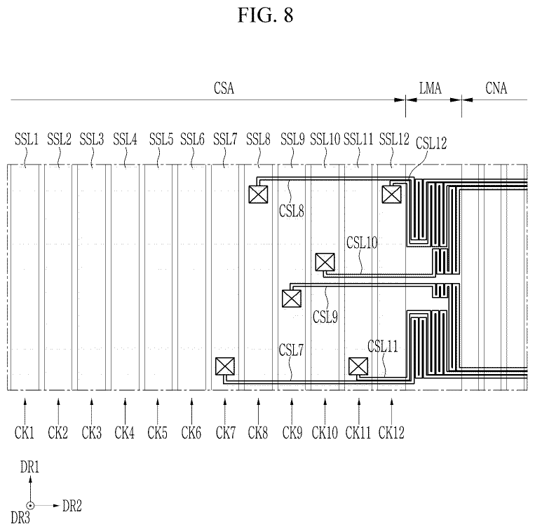

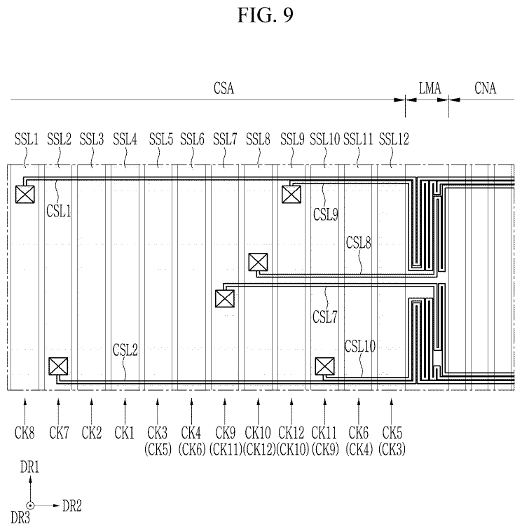

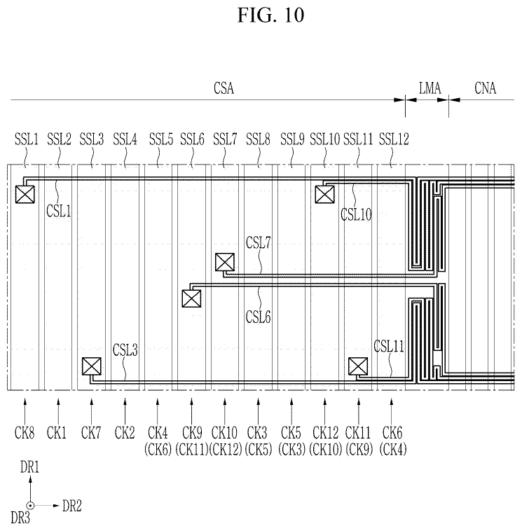

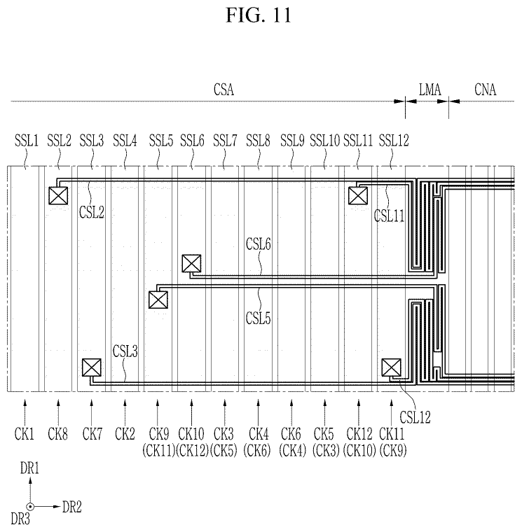

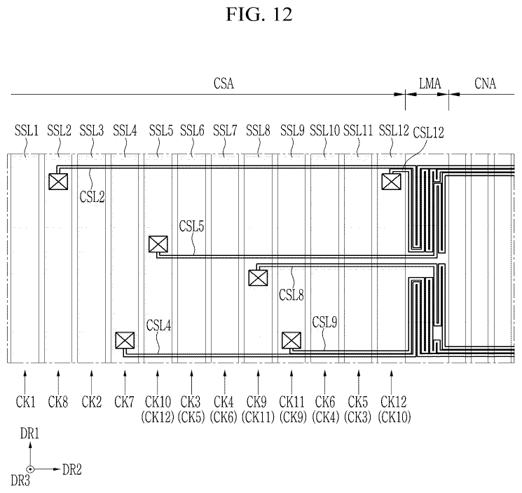

FIG. 8, FIG. 9, FIG. 10, FIG. 11, and FIG. 12 are diagrams each illustrating clock signals transmitted through clock signal lines of a second clock signal line group and connection with a second gate drive circuit in a display device according to an embodiment.

FIG. 8, FIG. 9, FIG. 10, FIG. 11, and FIG. 12 each show the connection between six of the clock signal lines and the second-2 gate drive circuit SDC2-2, but the connection between the remaining six clock signal lines and the second-1 gate drive circuit SDC2-1 can be understood by cross-referencing FIG. 6.

Referring to FIG. 8, the first to twelfth clock signal lines SSL1~SSL12 located in the clock signal line area CSA of the second clock signal line group may each transmit first to twelfth clock signals CK1~CK12. First to sixth clock signals CK1~CK6 may be applied to the second-1 gate drive circuit SDC2-1 and seventh to twelfth clock signals CK7~CK12 may be applied to the second-2 gate drive circuit SDC2-2. First to sixth clock connection lines CSL1~CSL6 or seventh to twelfth clock connection lines CSL7~CSL12 may connect first to sixth clock signal lines SSL1~SSL6 or seventh to twelfth clock signal lines SSL7~SSL12 with the second gate drive circuit SDC2-1 or SDC2-2 to apply first to sixth clock signals CK1~CK6 or seventh to twelfth clock signals CK7~CK12 to the second gate drive circuit SDC2-1 or SDC2-2. For example, when seventh to twelfth clock signals CK7~CK12 are applied to the second-2 gate drive circuit SDC2-2, seventh, ninth, and eleventh clock connection lines CSL7, CSL9, and CSL11 and eighth, tenth and twelfth clock connection lines CSL8, CSL10, and CSL12 may be located in the corresponding load matching area LMA. When first to sixth clock signals CK1~CK6 are applied to the second-1 gate drive circuit SDC2-1, first, third and fifth clock connection lines CSL1, CSL3, and CSL5 and second, fourth and sixth clock connection lines CSL2, CSL4, and CSL6 may be located in the corresponding load matching area LMA. Since the first to sixth clock signal lines SSL1~SSL6 are located farther from the second gate drive circuit SDC2 than the seventh to twelfth clock signal lines SSL7~SSL12, the length of the seventh to twelfth clock connection lines CSL7~CSL12 in the load matching area LMA can be made longer than the length of the first to sixth clock connection lines CSL1~CSL6 to reduce the resistance deviation between the first to twelfth clock connection lines CSL1~CSL12. Accordingly, the width of the load matching area LMA may be determined by the length of the seventh to twelfth clock connection lines CSL7~CSL12 located in the load matching area LMA. For example, the width of the load matching area LMA may be 147.8 μm.

Although the connection between the second clock signal line group and second gate drive circuit SDC2 has been described, this same connection can be equally applied to the connection between the first clock signal line group and the first gate drive circuit SDC1. Therefore, the explanation of the connection between the first clock signal line group and first gate drive circuit SDC1 is omitted and replaced by the explanation of the connection between the second clock signal line group and second gate drive circuit SDC2, and the same applies hereinafter.

Referring to FIG. 9, the first to twelfth clock signal lines SSL1~SSL12 in the clock signal line area CSA may not sequentially transmit the first to twelfth clock signals CK1~CK12, respectively. The first to twelfth clock signal lines SSL1~SSL12 may be matched differently from the order of the first to twelfth clock signals CK1~CK12. In other words, the order of the first to twelfth clock signals CK1~CK12 transmitted through the first to twelfth clock signal lines SSL1~SSL12 may be changed.

For example, the order of the first to twelfth clock signals CK1~CK12 may be changed so that the sum of distances between the clock signal lines transmitting clock signals CK7~CK12 applied to the second-2 gate drive circuit SDC2-2 and the second-2 gate drive circuit SDC2-2 is substantially equal to or similar to the sum of distances between the clock signal lines transmitting clock signals CK1-CK6 applied to the second-1 gate drive circuit SDC2-1 and the second-1 gate drive circuit SDC2-1. For instance, as shown in FIG. 9, the first to twelfth clock signal lines SSL1~SSL12 may sequentially transmit clock signals CK8, CK7, CK2, CK1, CK3, CK4, CK9, CK10, CK12, CK11, CK6, and CK5. Alternatively, the first to twelfth clock signal lines SSL1~SSL12 may sequentially transmit clock signals CK8, CK7, CK2, CK1, CK5, CK6, CK11, CK12, CK10, CK9, CK4, and CK3. The sum of distances between four clock signal lines SSL5, SSL6, SSL11, and SSL12 connected to the second-1 gate drive circuit SDC2-1 and the second-1 gate drive circuits SDC2-1 may be substantially equal to the sum of distances between four clock signal lines SSL7~SSL10 connected to the second-2 gate drive circuit SDC2-2 and the second-2 gate drive circuit SDC2-2. This is possible because the sum of distances between fifth and twelfth clock signal lines SSL5, SSL12 and the second-1 gate drive circuit SDC2-1, the sum of distances between sixth and eleventh clock signal lines SSL6 and SSL11 and the second-1 gate drive circuit SDC2-1, the sum of distances between seventh and tenth clock signal lines SSL7 and SSL10 and the second-2 gate drive circuit SDC2-2, and the sum of distances between eighth and ninth clock signal lines SSL8 and SSL9 and the second-2 gate drive circuit SDC2-2 may be substantially equal. Accordingly, the sum of lengths of clock connection lines CSL1, CSL2, and CSL7~CSL10 connected to the second-2 gate drive circuit SDC2-2 may be similar to the sum of lengths of clock connection lines CSL3~CSL6, CSL11, and CSL12 connected to the second-1 gate drive circuit SDC2-1.

The length increase of the clock connection lines CSL1~CSL12 in the load matching area LMA required for load adjustment of the clock connection lines CSL3~CSL6, CSL11, and CSL12 connected to the second-1 gate drive circuit SDC2-1 may be equal or similar to the length increase of the clock connection lines CSL1, CSL2, and CSL7~CSL10 in the load matching area LMA required for load adjustment of the clock connection lines CSL1, CSL2, and CSL7~CSL10 connected to the second-2 gate drive circuit SDC2-2. Accordingly, compared to the embodiment of FIG. 8 where the width of the load matching area LMA is determined by the length of the seventh to twelfth clock connection lines CSL7~CSL12, the width of the load matching area LMA can be reduced. For example, the width of the load matching area LMA may be 106 μm (approximately 28% reduction compared to the embodiment of FIG. 8).

The first to fourth clock signal lines SSL1~SSL4 transmitting clock signals relatively far from the second gate drive circuits SDC2-1, SDC2-2 may each transmit one of the first, second, seventh, and eighth clock signals CK1, CK2, CK7, and CK8. The first clock signal line SSL1 may transmit one of the first, second, seventh, and eighth clock signals CK1, CK2, CK7, and CK8, the second clock signal line SSL2 may transmit another one of the first, second, seventh, and eighth clock signals CK1, CK2, CK7, and CK8, the third clock signal line SSL3 may transmit yet another one of the first, second, seventh, and eighth clock signals CK1, CK2, CK7, and CK8, and the fourth clock signal line SSL4 may transmit the remaining one of the first, second, seventh, and eighth clock signals CK1, CK2, CK7, and CK8. That is, the arrangement order of clock signals CK8, CK7, CK2, and CK1 transmitted through the first to fourth clock signal lines SSL1~SSL4 may have 24 possibilities. For example, the first to fourth clock signal lines SSL1~SSL4 may sequentially transmit clock signals CK8, CK7, CK1, and CK2. The first to fourth clock signal lines SSL1~SSL4 may sequentially transmit clock signals CK8, CK1, CK7, and CK2. The first to fourth clock signal lines SSL1~SSL4 may sequentially transmit clock signals CK1, CK8, CK7, and CK2. The first to fourth clock signal lines SSL1~SSL4 may sequentially transmit clock signals CK1, CK8, CK2, and CK7. The first to fourth clock connection lines CSL1~CSL4 may be formed shorter in the load matching area LMA than other clock connection lines CSL5~CSL12, so the order change of clock signals CK8, CK7, CK2, and CK1 transmitted through the first to fourth clock signal lines SSL1~SSL4 may have relatively less influence on RC delay of the clock signals CK8, CK7, CK2, and CK1.

Referring to FIG. 10, the clock signals transmitted through the fifth to twelfth clock signal lines SSL5~SSL12 are different from those in the aforementioned embodiments. The fifth to twelfth clock signal lines SSL5~SSL12 may sequentially transmit clock signals CK4, CK9, CK10, CK3, CK5, CK12, CK11, and CK6. Alternatively, the fifth to twelfth clock signal lines SSL5~SSL12 may transmit, in order, clock signals CK6, CK11, CK12, CK5, CK3, CK10, CK9, and CK4. The first to fourth clock signal lines SSL1~SSL4 may each transmit one of the first, second, seventh, and eighth clock signals CK1, CK2, CK7, and CK8, and, as shown, may sequentially transmit clock signals CK8, CK1, CK7, and CK2. The sum of distances between four clock signal lines SSL7~SSL10 connected to the second-2 gate drive circuit SDC2-2 and the second-2 gate drive circuit SDC2-2 may be substantially equal to the sum of distances between four clock signal lines SSL5, SSL6, SSL11, and SSL12 connected to the second-1 gate drive circuit SDC2-1 and the second-1 gate drive circuit SDC2-1. Accordingly, the sum of lengths of clock connection lines CSL2, CSL3, and CSL7~CSL10 connected to the second-2 gate drive circuit SDC2-2 may be similar to the sum of lengths of clock connection lines CSL1, CSL4~CSL6, CSL11, and CSL12 connected to the second-1 gate drive circuit SDC2-1. Thus, as described above, the width of the load matching area LMA can be reduced compared to the embodiment of FIG. 8.

Referring to FIG. 11, the clock signals transmitted through the fifth to twelfth clock signal lines SSL5~SSL12 are different from those in the aforementioned embodiments. The fifth to twelfth clock signal lines SSL5~SSL12 may sequentially transmit clock signals CK9, CK10, CK3, CK4, CK6, CK5, CK12, and CK11. Alternatively, the fifth to twelfth clock signal lines SSL5~SSL12 may transmit, in order, clock signals CK11, CK12, CK5, CK6, CK4, CK3, CK10, and CK9. The first to fourth clock signal lines SSL1~SSL4 may each transmit one of the first, second, seventh, and eighth clock signals CK1, CK2, CK7, and CK8, and, as shown, may sequentially transmit clock signals CK1, CK8, CK7, and CK2. The sum of distances between four clock signal lines SSL5, SSL8, SSL9, and SSL12 connected to the second-2 gate drive circuit SDC2-2 and the second-2 gate drive circuit SDC2-2 may be substantially equal to the sum of distances between four clock signal lines SSL6, SSL7, SSL10, and SSL11 connected to the second-1 gate drive circuit SDC2-1 and the second-1 gate drive circuit SDC2-1. Accordingly, the sum of lengths of clock connection lines CSL2, CSL4, CSL5, CSL8, CSL9, and CSL12 connected to the second-2 gate drive circuit SDC2-2 may be similar to the sum of lengths of clock connection lines CSL1, CSL3, CSL6, CSL7, CSL10, and CSL11 connected to the second-1 gate drive circuit SDC2-1. Thus, as described above, the width of the load matching area LMA can be reduced compared to the embodiment of FIG. 8.

Referring to FIG. 12, the clock signals transmitted through the fifth to twelfth clock signal lines SSL5~SSL12 are different from those in the aforementioned embodiments. The fifth to twelfth clock signal lines SSL5~SSL12 may sequentially transmit, in order, clock signals CK10, CK3, CK4, CK9, CK11, CK6, CK5, and CK12. Alternatively, the fifth to twelfth clock signal lines SSL5~SSL12 may sequentially transmit clock signals CK12, CK5, CK6, CK11, CK9, CK4, CK3, and CK10. The first to fourth clock signal lines SSL1~SSL4 may each transmit one of the first, second, seventh, and eighth clock signals CK1, CK2, CK7, and CK8, and, as shown, may sequentially transmit clock signals CK1, CK8, CK2, and CK7. The sum of distances between four clock signal lines SSL5, SSL8, SSL9, SSL12 connected to the second-2 gate drive circuit SDC2-2 and the second-2 gate drive circuit SDC2-2 may be substantially equal to the sum of distances between four clock signal lines SSL6, SSL7, SSL10, and SSL11 connected to the second-1 gate drive circuit SDC2-1 and the second-1 gate drive circuit SDC2-1. This is possible because the sum of distances between fifth and twelfth clock signal lines SSL5, SSL12 and the second-2 gate drive circuit SDC2-2, the sum of distances between eighth and ninth clock signal lines SSL8 and SSL9 and the second-2 gate drive circuit SDC2-2, the sum of distances between sixth and eleventh clock signal lines SSL6 and SSL11 and the second-1 gate drive circuit SDC2-1, and the sum of distances between seventh and tenth clock signal lines SSL7 and SSL10 and the second-1 gate drive circuit SDC2-1 may be substantially equal. Thus, as described above, the width of the load matching area LMA can be reduced compared to the embodiment of FIG. 8.

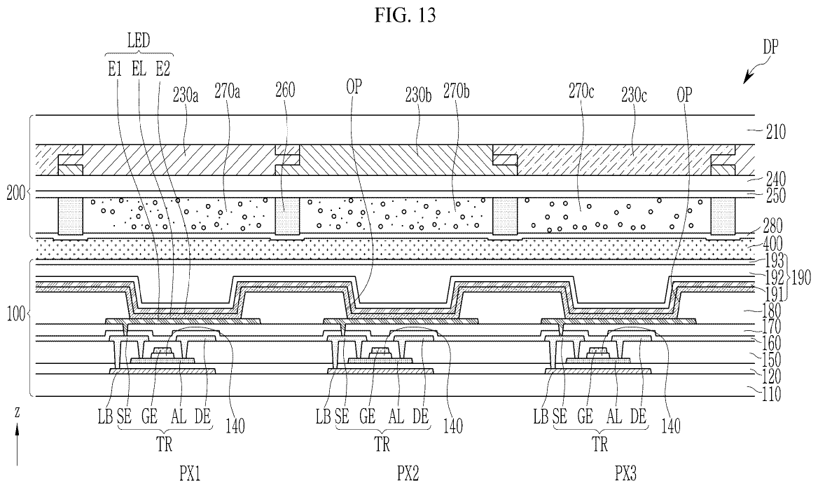

FIG. 13 is a schematic cross-sectional view of a display area of a display device according to an embodiment.

Referring to FIG. 13, the display panel DP may include a display portion 100, a color conversion portion 200, and a filling material 400 located between the display portion 100 and the color conversion portion 200.

The display portion 100 may basically include a substrate 110, a transistor TR formed on the substrate 110, and a light emitting diode LED connected to the transistor TR. The transistor TR may include a semiconductor layer AL, a gate electrode GE, a first electrode SE, and a second electrode DE. The first electrode SE may be connected to a first region of the semiconductor layer AL and a light blocking pattern LB, and the second electrode DE may be connected to a second region of the semiconductor layer AL. The transistor TR shown may be the first transistor T1.

The substrate 110 may include a material having a rigid characteristic, such as glass, or a material having a flexible characteristic, such as plastic. For example, the substrate 110 may be a glass substrate. The substrate 110 may also include a polymeric material such as, for example, polyimide, polyamide, or polyethylene terephthalate.

A light blocking pattern LB may be located on the substrate 110. The light blocking pattern LB may prevent external light from reaching the semiconductor layer AL of the transistor TR to prevent deterioration of the semiconductor layer AL characteristics. The light blocking pattern LB may control leakage current of the transistor TR, particularly the driving transistor whose current characteristics are important in the display device. The light blocking pattern LB may function as an electrode to which a specific voltage is applied. In this case, the voltage-current characteristic graph of the transistor TR may have a smaller current variation rate in the saturation region, improving the characteristics of the transistor TR. The light blocking pattern LB may include metals, such as copper (Cu), aluminum (Al), titanium (Ti), molybdenum (Mo), tungsten (W), or the like, and may be a single layer or multiple layers. For example, the first conductive layer may have a double-layer structure, such as titanium (Ti)/copper (Cu). The aforementioned clock connection lines CCL1~CCL12 and CSL1~CSL12 may be formed in the same layer with the same material as the light blocking pattern LB.

A buffer layer 120 may be located on the light blocking pattern LB. The buffer layer 120 may block impurities from the substrate 110 during formation of the semiconductor layer AL to improve the characteristics of the semiconductor layer AL, and may planarize the surface of the substrate 110 to relieve stress of the semiconductor layer AL. The buffer layer 120 may include at least one inorganic insulating material, such as silicon nitride (SiNₓ), silicon oxide (SiOₓ) and silicon oxynitride (SiOₓN_{y}). The buffer layer 120 may also include amorphous silicon.

The semiconductor layer AL may be located on the buffer layer 120. The semiconductor layer AL may include a first region, a second region, and a channel region between the first region and the second region. The channel region of the semiconductor layer AL may overlap with the light blocking pattern LB. The semiconductor layer AL may include an oxide semiconductor. For example, the semiconductor layer AL may include an oxide semiconductor such as IGZO (indium-gallium-zinc oxide) containing at least one of zinc (Zn), indium (In), gallium (Ga), tin (Sn), and mixtures thereof. The semiconductor layer AL may include polycrystalline silicon or amorphous silicon, and for example, may include low-temperature polysilicon (LTPS).

A first insulating layer 140 may be located on the semiconductor layer AL. The first insulating layer 140 may be a gate insulating layer. The first insulating layer 140 may be formed in an area overlapping with the gate electrode GE. This structure may be formed by etching the first insulating layer 140 during a photolithography process for forming the gate electrode GE. The first insulating layer 140 may also be formed to substantially cover the entire substrate 110. The first insulating layer 140 may be an inorganic insulating layer including at least one inorganic insulating material, such as silicon oxide, silicon nitride and silicon oxynitride, and may be a single layer or multiple layers.

The gate electrode GE of the transistor TR may be located on the first insulating layer 140. The gate electrode GE may overlap with the channel region of the corresponding semiconductor layer AL. The gate electrode GE may overlap with the light blocking pattern LB. The gate electrode GE may include metals, such as copper (Cu), aluminum (Al), titanium (Ti), molybdenum (Mo), tungsten (W), and may be a single layer or multiple layers. For example, the second conductive layer may have a double-layer structure, such as titanium (Ti)/copper (Cu). The aforementioned clock connection lines CCL1-CSL12 and CSL1-CSL12 or clock signal lines CK1~CK12 may be formed in the same layer with the same material as the gate electrode GE.

A second insulating layer 150 may be located on the gate electrode GE. The second insulating layer 150 may be an interlayer insulating layer. The second insulating layer 150 may be an inorganic insulating layer including at least one inorganic insulating material, such as silicon oxide, silicon nitride and silicon oxynitride, and may be a single layer or multiple layers.

The first electrode SE and second electrode DE of the transistor TR may be located on the second insulating layer 150. One of the first electrode SE and second electrode DE may be a source electrode and the other may be a drain electrode. The first electrode SE and second electrode DE may be connected to the first region and second region of the semiconductor layer AL through contact holes formed in the second insulating layer 150, respectively. The first electrode SE may be connected to the light blocking pattern LB through a contact hole formed in the second insulating layer 150 and buffer layer 120. The first electrode SE and second electrode DE may include at least one metal, such as copper (Cu), aluminum (Al), titanium (Ti), molybdenum (Mo), and tungsten (W), and may be a single layer or multiple layers. The third conductive layer may include at least one transparent conductive material, such as indium tin oxide (ITO) and indium zinc oxide (IZO). For example, the third conductive layer may have a triple-layer structure, such as titanium (Ti)/copper (Cu)/ITO. The aforementioned clock signal lines CK1~CK12 may be formed in the same layer with the same material as the first electrode SE and second electrode DE.

A third insulating layer 160 may be located on the first electrode SE and second electrode DE. The third insulating layer 160 may be a passivation layer. The third insulating layer 160 may be an inorganic insulating layer including at least one inorganic insulating material, such as silicon oxide, silicon nitride, and silicon oxynitride, and may be a single layer or multiple layers.

A first organic insulating layer 170 may be located on the third insulating layer 160. The first organic insulating layer 170 may be a planarization layer. The first organic insulating layer 170 may include organic insulating materials, such as general-purpose polymers like polymethyl methacrylate (poly(methyl methacrylate)) and polystyrene, polymer derivatives having phenol groups, acrylic polymers, imide-based polymers (e.g., polyimide), siloxane-based polymers, or the like.

A pixel electrode E1 of the light emitting diode LED may be located on the first organic insulating layer 170. The pixel electrode E1 may be connected to the first electrode SE through a contact hole formed in the first organic insulating layer 170 and third insulating layer 160. The pixel electrode E1 may be formed of reflective conductive materials or semi-transmissive conductive materials, and may also be formed of transparent conductive materials. The pixel electrode E1 may include at least one transparent conductive material, such as indium tin oxide (ITO) and indium zinc oxide (IZO). The pixel electrode E1 may include at least one metal, such as lithium (Li), calcium (Ca), aluminum (Al), silver (Ag), magnesium (Mg), and gold (Au). The pixel electrode E1 may have a multi-layer structure, and for example, may have a triple-layer structure, such as ITO/silver (Ag)/ITO.

A second organic insulating layer 180 may be located on the pixel electrode E1. The second organic insulating layer 180 may be a pixel defining layer or bank. The second organic insulating layer 180 may have an opening OP formed in an area corresponding to the pixel electrode E1. The second organic insulating layer 180 may include at least one organic insulating materials, such as acrylic polymers, imide-based polymers, and amide-based polymers. The second organic insulating layer 180 may include black pigments. For example, the second organic insulating layer 180 may include a polyimide binder and a mixture of red, green, and blue pigments. The second organic insulating layer 180 may include a cardo binder resin and a mixture of lactam black pigments and blue pigments. The second organic insulating layer 180 may include carbon black. The second organic insulating layer 180 including black pigments may improve contrast ratio and prevent reflection by metal layers located below.

An emission layer EL may be located on the pixel electrode E1. The emission layer EL may be located across pixels PX1, PX2, and PX3. The emission layer EL may be continuously located across the entire display area DA. The emission layer EL may contact the pixel electrode E1 through the opening OP of the second organic insulating layer 180. The emission layer EL may include light emitting materials that emit blue light. The emission layer EL may also include light emitting materials that emit red light or green light in addition to blue light. The emission layer EL may include multiple emission layers, and the multiple emission layers may include emission layers that emit the same color of light or emission layers that emit different colors of light. For example, the emission layer EL may have a structure where three blue emission layers are stacked. Alternatively, the emission layer EL may have a structure where three blue emission layers and one green emission layer are stacked. In addition to the emission layer EL, a hole injection layer, hole transport layer, electron transport layer, and electron injection layer may be located on the pixel electrode E1.

A common electrode E2 may be located on the emission layer EL. The common electrode E2 may be located across pixels PX1, PX2, and PX3. The common electrode E2 may be continuously located across the entire display area DA. The common electrode E2 may include at least one metal, such as calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), and lithium (Li). The common electrode E2 may include at least one transparent conductive oxide, such as indium tin oxide (ITO) and indium zinc oxide (IZO). The common electrode E2 may have a multi-layer structure, and for example, may have a double-layer structure, such as magnesium (Mg)/silver (Ag).

The pixel electrode E1, emission layer EL, and common electrode E2 may constitute a light emitting diode LED which may be an organic light emitting diode. The pixel electrodes E1 may be individually provided for each pixel PX1, PX2, and PX3 to receive driving current. The common electrode E2 may be commonly provided to the pixels PX1, PX2, and PX3 to receive a common voltage ELVSS. The pixel electrode E1 may be a hole injection electrode called an anode, and the common electrode E2 may be an electron injection electrode called a cathode, or vice versa. The opening OP of the second organic insulating layer 180 may correspond to the emission area of the light emitting diode LED.

An encapsulation layer 190 may be located on the common electrode E2. The encapsulation layer 190 may seal the light emitting diodes LED and prevent infiltration of moisture or oxygen from the outside. The encapsulation layer 190 covers the entire display area DA, and the edge of the encapsulation layer 190 may be located in the non-display area NA. The encapsulation layer 190 may be a thin film encapsulation layer including a first inorganic layer 191, an organic layer 192, and a second inorganic layer 193. The first inorganic layer 191 and second inorganic layer 193 may mainly prevent infiltration of moisture, and the like, and the organic layer 192 may mainly planarize the surface of the encapsulation layer 190, particularly the surface of the second inorganic layer 193 in the display area DA. The first inorganic layer 191 and second inorganic layer 193 may include at least one inorganic insulating material, such as silicon oxide and silicon nitride. The organic layer 192 may include at least one organic material, such as acrylic resins, methacrylic resins, polyisoprene, vinyl resins, epoxy resins, urethane resins, cellulose resins, perylene resins, and the like.

The color conversion portion 200 may be located on the encapsulation layer 190 of the display portion 100.

The color conversion portion 200 may include a substrate 210. The substrate 210 may include at least one insulating material, such as glass and plastic, and for example, substrate 210 may be a glass substrate.

In a direction toward the display portion 100, color filters 230a, 230b, and 230c may be located on the substrate 210. In the display area DA, the color filters 230a, 230b, and 230c may be disposed in areas corresponding to the openings OP of the second organic insulating layer 180. The color filters 230a, 230b, and 230c may include a first color filter 230a that transmits light of a first wavelength and absorbs light of other wavelengths, a second color filter 230b that transmits light of a second wavelength and absorbs light of other wavelengths, and a third color filter 230c that transmits light of a third wavelength and absorbs light of other wavelengths. The first color filter 230a, second color filter 230b, and third color filter 230c may overlap with the first pixel PX1, second pixel PX2, and third pixel PX3, respectively. Accordingly, the purity of first wavelength light (corresponding to first pixel PX1), second wavelength light (corresponding to second pixel PX2), and third wavelength light (corresponding to third pixel PX3) emitted outside the display panel DP can be improved. The first wavelength light, second wavelength light, and third wavelength light may be red light, green light, and blue light, respectively.

The first color filter 230a, second color filter 230b, and third color filter 230c may overlap with each other at the boundary portions of pixels PX1, PX2, and PX3 to form a light blocking area. As shown, all three of the first color filter 230a, second color filter 230b, and third color filter 230c may overlap to form a light blocking area, but two color filters may overlap to form a light blocking area. For example, the first color filter 230a and second color filter 230b may overlap at the boundary portion between first pixel PX1 and second pixel PX2, the second color filter 230b and third color filter 230c may overlap at the boundary portion between second pixel PX2 and third pixel PX3, and the third color filter 230c and first color filter 230a may overlap at the boundary portion between third pixel PX3 and first pixel PX1. In the non-display area NA, the first color filter 230a, second color filter 230b, and third color filter 230c may overlap with each other to form a light blocking area. The third color filter 230c, first color filter 230a, and second color filter 230b may be stacked in this order on the substrate 210, but may be stacked in a different order. Instead of overlapping color filters 230a, 230b, and 230c, a light blocking member may be formed to provide a light blocking area.

A low refractive index layer 240 may be located on the color filters 230a, 230b, and 230c. The low refractive index layer 240 may be located to cover the entire substrate 210. The low refractive index layer 240 may include at least one organic material or at least one inorganic material having a low refractive index. The refractive index of the low refractive index layer 240 may be about 1.1 to about 1.3. The low refractive index layer 240 may be arranged on a different layer. For example, the low refractive index layer 240 may be located between the color conversion layers 270a and 270b and transmission layer 270c and the second capping layer 280. The color conversion portion 200 may also include multiple low refractive index layers. For example, in addition to the low refractive index layer 240 located between the color filters 230a, 230b, and 230c and the first capping layer 250 as shown, the color conversion portion 200 may further include a low refractive index layer located between the color conversion layers 270a and 270b and transmission layer 270c and the second capping layer 280.

A first capping layer 250 may be located on the low refractive index layer 240. The first capping layer 250 may be located to entirely cover the low refractive index layer 240 and may protect the low refractive index layer 240. The first capping layer 250 may include at least one inorganic insulating material, such as silicon oxide, silicon nitride, and silicon oxynitride, and may be a single layer or multiple layers.

A bank 260 may be located on the first capping layer 250. The bank 260 may be located in the display area DA and may overlap with the second organic insulating layer 180 in a plan view. The bank 260 may overlap with the light blocking area where the first color filter 230a, second color filter 230b, and third color filter 230c overlap. The bank 260 may be located at the boundary portions of pixels PX1, PX2, and PX3. The bank 260 may partition pixel areas. The bank 260 may include at least one organic insulating material, such as acrylic polymers, imide-based polymers, and amide-based polymers. The bank 260 may be a black bank including colored pigments, such as black pigments, but may also be transparent.

A first color conversion layer 270a, a second color conversion layer 270b, and a transmission layer 270c may be located on the first capping layer 250. The first color conversion layer 270a, second color conversion layer 270b, and transmission layer 270c may be located within spaces (i.e., openings of the bank 260) defined by the bank 260. The first color conversion layer 270a, second color conversion layer 270b, and transmission layer 270c may be partitioned or separated by the bank 260. The first color conversion layer 270a, second color conversion layer 270b, and transmission layer 270c may be formed by an inkjet printing process.

The first color conversion layer 270a may overlap with the first color filter 230a. The first color conversion layer 270a may overlap with the light emitting diode LED corresponding to the first pixel PX1 and may convert light incident from the light emitting diode LED into light of a first wavelength. The light of the first wavelength may be red light having a maximum emission peak wavelength of about 600 nm to about 650 nm, for example, about 620 nm to about 650 nm.

The second color conversion layer 270b may overlap with the second color filter 230b. The second color conversion layer 270b may overlap with the light emitting diode LED corresponding to the second pixel PX2 and may convert light incident from the light emitting diode LED into light of a second wavelength. The light of the second wavelength may be green light having a maximum emission peak wavelength of about 500 nm to about 550 nm, for example, about 510 nm to about 550 nm.

The transmission layer 270c may overlap with the third color filter 230c. The transmission layer 270c may overlap with the light emitting diode LED corresponding to the third pixel PX3 and may transmit light incident from the light emitting diode LED. The light transmitted through the transmission layer 270c may be light of a third wavelength. The light of the third wavelength may be blue light having a maximum emission peak wavelength of about 380 nm to about 480 nm, for example, about 420 nm or more, about 430 nm or more, about 440 nm or more, or about 445 nm or more, and about 470 nm or less, about 460 nm or less, or about 455 nm or less.

The first color conversion layer 270a and second color conversion layer 270b may include first quantum dots and second quantum dots, respectively. For example, light incident to the first color conversion layer 270a may be converted and emitted as light of the first wavelength by the first quantum dots. Light incident to the second color conversion layer 270b may be converted and emitted as light of the second wavelength by the second quantum dots. The first color conversion layer 270a, second color conversion layer 270b, and transmission layer 270c may include scattering particles. The scattering particles may scatter light incident to the first color conversion layer 270a, second color conversion layer 270b, and transmission layer 270c to improve light efficiency.

A second capping layer 280 may be located on the bank 260. The second capping layer 280 may be located to entirely cover the substrate 210. The second capping layer 280 may cover the first color conversion layer 270a, second color conversion layer 270b, and transmission layer 270c. The second capping layer 280 may include at least one inorganic insulating material, such as silicon oxide, silicon nitride, and silicon oxynitride, and may be a single layer or multiple layers.

The low refractive index layer 240, first capping layer 250, and second capping layer 280 may cover the side surfaces of the color filters 230a, 230b, and 230c at the edge portion of the color conversion portion 200. The low refractive index layer 240, first capping layer 250, and second capping layer 280 may be formed up to the edge of the substrate 210, and the low refractive index layer 240 may contact the substrate 210 at the edge of the color conversion portion 200. The low refractive index layer 240, first capping layer 250, and second capping layer 280 may form a barrier member that prevents infiltration of moisture, oxygen, or the like from the edge of the color conversion portion 200.

A filling material 400 may be located between the color conversion portion 200 and the display portion 100. The filling material 400 may fill the space between the display portion 100 and the color conversion portion 200 to increase the press resistance between the display portion 100 and the color conversion portion 200. One surface of the filling material 400 may contact the second capping layer 280 and the other surface of the filling material 400 may contact the encapsulation layer 190. The filling material 400 may be formed by coating a filling material on the second capping layer 280 overlapping the display portion 100 and then curing. The filling material 400 may include at least one organic material, such as epoxy resin.

Although the embodiments have been described in detail above, the scope of the disclosure is not limited to these and various changes and modifications may be made within the scope of the disclosure as defined by the following claims and their equivalents.

What is claimed is:

1. A display device comprising:
a display panel including a display area where pixels displaying images are located and a non-display area adjacent to the display area; and
a gate driver including gate drive circuits providing scan signals to the pixels and clock signal lines transmitting clock signals to the gate drive circuits,
wherein the non-display area includes a drive circuit area where the gate drive circuits are located, a clock signal line area where the clock signal lines transmitting clock signals are located, and a load matching area between the gate drive circuit area and the clock signal line area,
wherein the gate drive circuits include a second-1 gate drive circuit and a second-2 gate drive circuit disposed along a first direction, and
wherein a sum of distances between four clock signal lines among the clock signal lines electrically connected to the second-1 gate drive circuit and the second-1 gate drive circuit is substantially equal to a sum of distances between four clock signal lines among the clock signal lines electrically connected to the second-2 gate drive circuit and the second-2 gate drive circuit.

2. The display device of claim 1, further comprising clock connection lines electrically connecting the clock signal lines and the second-1 and second-2 gate drive circuits,
wherein the clock connection lines are bent in the load matching area.

3. The display device of claim 1, wherein the clock signals include first to twelfth clock signals sequentially phase-delayed, and
wherein the four clock signal lines electrically connected to the second-1 gate drive circuit transmit third to sixth clock signals, and the four clock signal lines electrically connected to the second-2 gate drive circuit transmit ninth to twelfth clock signals.

4. The display device of claim 3, wherein the second-1 gate drive circuit is electrically connected to clock signal lines transmitting the first and second clock signals among the clock signal lines, and the second-2 gate drive circuit is electrically connected to clock signal lines transmitting the seventh and eighth clock signals among the clock signal lines.

5. The display device of claim 4, wherein the clock signal lines include first to twelfth clock signal lines sequentially positioned in a second direction crossing the first direction, and
wherein the first to twelfth clock signal lines do not sequentially transmit the first to twelfth clock signals.

6. The display device of claim 5, wherein the first to fourth clock signal lines each transmit one of the first, second, seventh, and eighth clock signals.

7. The display device of claim 5, wherein the fifth and twelfth clock signal lines each transmit one of the third and fifth clock signals, the sixth and eleventh clock signal lines each transmit one of the fourth and sixth clock signals, the seventh and tenth clock signal lines each transmit one of the ninth and eleventh clock signals, and the eighth and ninth clock signal lines each transmit one of the tenth and twelfth clock signals.

8. The display device of claim 5, wherein the fifth and twelfth clock signal lines each transmit one of the fourth and sixth clock signals, the sixth and eleventh clock signal lines each transmit one of the ninth and eleventh clock signals, the seventh and tenth clock signal lines each transmit one of the tenth and twelfth clock signals, and the eighth and ninth clock signal lines each transmit one of the third and fifth clock signals.

9. The display device of claim 5, wherein the fifth and twelfth clock signal lines each transmit one of the ninth and eleventh clock signals, the sixth and eleventh clock signal lines each transmit one of the tenth and twelfth clock signals, the seventh and tenth clock signal lines each transmit one of the third and fifth clock signals, and the eighth and ninth clock signal lines each transmit one of the fourth and sixth clock signals.

10. The display device of claim 5, wherein the fifth and twelfth clock signal lines each transmit one of the tenth and twelfth clock signals, the sixth and eleventh clock signal lines each transmit one of the third and fifth clock signals, the seventh and tenth clock signal lines each transmit one of the fourth and sixth clock signals, and the eighth and ninth clock signal lines each transmit one of the ninth and eleventh clock signals.

11. An electronic device comprising a display module, a processor, and a memory, wherein the display module comprises:
a display panel including a display area where pixels displaying images are located and a non-display area adjacent to the display area;
a gate driver including gate drive circuits providing scan signals to the pixels; and
clock signal lines transmitting clock signals to the gate driver,
wherein the non-display area includes a drive circuit area where the gate drive circuits are located, a clock signal line area where the clock signal lines transmitting clock signals are located, and a load matching area between the gate drive circuit area and the clock signal line area,
wherein the gate drive circuits include a second-1 gate drive circuit and a second-2 gate drive circuit disposed along a first direction, and
wherein a sum of distances between four clock signal lines among the clock signal lines electrically connected to the second-1 gate drive circuit and the second-1 gate drive circuit is substantially equal to a sum of distances between four clock signal lines among the clock signal lines electrically connected to the second-2 gate drive circuit and the second-2 gate drive circuit.

12. The electronic device of claim 11, wherein the display module further comprises clock connection lines electrically connecting the clock signal lines and the second-1 and second-2 gate drive circuits, and
wherein the clock connection lines are bent in the load matching area.

13. The electronic device of claim 11, wherein the clock signals include first to twelfth clock signals sequentially phase-delayed, and
wherein the four clock signal lines electrically connected to the second-1 gate drive circuit transmit third to sixth clock signals, and the four clock signal lines electrically connected to the second-2 gate drive circuit transmit ninth to twelfth clock signals.

14. The electronic device of claim 13, wherein the second-1 gate drive circuit is electrically connected to clock signal lines transmitting the first and second clock signals among the clock signal lines, and the second-2 gate drive circuit is electrically connected to clock signal lines transmitting the seventh and eighth clock signals among the clock signal lines.

15. The electronic device of claim 14, wherein the clock signal lines include first to twelfth clock signal lines sequentially positioned in a second direction crossing the first direction, and
wherein the first to twelfth clock signal lines do not sequentially transmit the first to twelfth clock signals.

16. The electronic device of claim 15, wherein the first to fourth clock signal lines each transmit one of the first, second, seventh, and eighth clock signal lines.

17. The electronic device of claim 15, wherein the fifth and twelfth clock signal lines each transmit one of the third and fifth clock signals, the sixth and eleventh clock signal lines each transmit one of the fourth and sixth clock signals, the seventh and tenth clock signal lines each transmit one of the ninth and eleventh clock signals, and the eighth and ninth clock signal lines each transmit one of the tenth and twelfth clock signals.

18. The electronic device of claim 15, wherein the fifth and twelfth clock signal lines each transmit one of the fourth and sixth clock signals, the sixth and eleventh clock signal lines each transmit one of the ninth and eleventh clock signals, the seventh and tenth clock signal lines each transmit one of the tenth and twelfth clock signals, and the eighth and ninth clock signal lines each transmit one of the third and fifth clock signals.

19. The electronic device of claim 15, wherein the fifth and twelfth clock signal lines each transmit one of the ninth and eleventh clock signals, the sixth and eleventh clock signal lines each transmit one of the tenth and twelfth clock signals, the seventh and tenth clock signal lines each transmit one of the third and fifth clock signals, and the eighth and ninth clock signal lines each transmit one of the fourth and sixth clock signals.

20. The electronic device of claim 15, wherein the fifth and twelfth clock signal lines each transmit one of the tenth and twelfth clock signals, the sixth and eleventh clock signal lines each transmit one of the third and fifth clock signals, the seventh and tenth clock signal lines each transmit one of the fourth and sixth clock signals, and the eighth and ninth clock signal lines each transmit one of the ninth and eleven clock signals.
